(19) United States
(12) Patent Application Publication
(10) Pub. No.: US 2007/0254094 A1
(43) Pub. Date: Nov. 1, 2007

(54) Method and apparatus for controlling dispense operations in a track lithography tool

(75) Inventor: Y. Sean Lin, Irvine, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/414,133

(22) Filed: Apr. 27, 2006

(51) Int. Cl. C23C 16/52; G06F 19/00; B05C 11/00

(52) U.S. Cl. 427/8; 700/121; 118/696

(57) ABSTRACT

A method of dispensing a photolithography chemical onto a substrate in a track lithography tool includes determining the volume for each of a number of target volumes for a photolithography process. A pump control parameter is calculated for each target volume, as determined by a fitting a characteristic function to incremental volume-based characteristic factors as a function of the target volume, then determining the appropriate control parameter for a given target volume. In one embodiment, the control parameter is a number of drive pulses to be applied to a displacement pump motor to displace a selected volume of chemical and thus obtain the desired volume target. Control parameters also can be determined for each step of a multiple step dispense process. The method further includes providing a control signal to the dispense pump to control accurate delivery of the photolithography chemical to the substrate.

### BACKGROUND OF THE INVENTION

The present invention relates generally to the field of substrate processing equipment. More particularly, the present invention relates to a method and apparatus for providing calibration for semiconductor process chemistry. Merely by way of example, the method and apparatus of the present invention are used to control the volume of chemical dispensed in a photolithography coating system. The method and apparatus can be applied to other processes for semiconductor substrates, for example those used in the formation of integrated circuits.

Modern integrated circuits contain millions of individual elements that are formed by patterning the materials, such as silicon, metal, and/or dielectric layers, that make up the integrated circuit to sizes that are small fractions of a micrometer. The technique presently used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer, and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool, and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to shrink the size of semiconductor devices. The reduced feature sizes have caused the industry's tolerance to process variability to shrink, which in turn has resulted in semiconductor manufacturing specifications having more stringent requirements for process uniformity and repeatability. An important factor in minimizing process variability during track lithography processing sequences is to ensure that every substrate processed within the track lithography tool for a particular application has the same “wafer history.” A substrate's wafer history is generally monitored and controlled by process engineers to ensure that all of the device fabrication processing variables that may later affect a device's performance are controlled, so that all substrates in the same batch are always processed the same way.

One component of the “wafer history” includes the thickness, uniformity, repeatability, and other characteristics of the photolithography chemistry, which includes, without limitation, photoresist, developer, and solvents. Generally, a substrate such as a semiconductor wafer is rotated on a spin chuck at predetermined speeds during photolithography processes while liquids and gases such as solvents, photoresist (resist), developer, and the like are dispensed onto the surface of the substrate. Typically, the wafer history will depend on the process parameters associated with the photolithography process.

As an example, an inadequate volume of photoresist dispensed during a coating operation will generally impact the uniformity and thickness of coatings formed on the substrate. Additionally, the dispense rate of the photoresist will generally impact film properties, including the lateral spreading of the resist in the plane of the substrate. Therefore, it is desirable to control the volume and dispense rate of the photoresist applied to the substrate with respect to both the accuracy (e.g., total volume per dispense event) and repeatability (e.g., difference in volume per dispense over a series of dispense events) of the dispense process.

For some photolithography chemical dispense applications, offset adjustments are provided on pumps used to dispense fluids. For example, in some dispense applications, the variation of dispensed fluid volume as a function of target volume is approximated by a linear fit and offset adjustments are calculated in an effort to compensate for discrepancies between desired and actual dispense volumes. In some applications, a calibration procedure looks at a total dispense volume error for a process and calculates an adjustment to be applied to the dispense pump. However, these adjustments do not provide the level of control desirable for current and future track lithography tools, particularly for processes where the dispense volume and/or flow rate varies during the process. For example, in a dispense process with four steps that each can include a different dispense volume and/or flow rate, simply calculating an adjustment for the entire process will not produce an accurate adjustment for any of the individual steps of the process. In fact, using a single adjustment can actually increase the error in at least some of the individual steps. Accordingly, further improvements are desired and are continuously sought by process engineers. Therefore, there is a need in the art for improved methods and apparatus for controlling the dispense variables in a photolithography system.

### SUMMARY OF THE INVENTION

In accordance with various embodiments of the present invention, techniques related to the field of substrate processing equipment are provided. More particularly, the present invention relates to a method and apparatus for providing calibration for semiconductor process chemistry. Merely by way of example, the method and apparatus of the present invention are used to control the volume of chemical dispensed in a photolithography coating system. The method and apparatus can be applied to other processes for semiconductor substrates, for example those used in the formation of integrated circuits.

According to an embodiment of the present invention, an amount of photolithography chemical is dispensed at each of a plurality of target volumes. This can include a single or multiple dispense cycles for each target volume. A dispense volume is measured for each of the plurality of target volumes. Where multiple dispense cycles are used, this can involve calculating an average volume for each target volume. A pump characteristic factor is determined for each of the plurality of target volumes based on the measured dispense volume. A pump characteristic function then is fit to the characteristic factors for each of the plurality of target volumes. The characteristic function can be a linear function or any other appropriate function. Once the characteristic function is obtained, a pump control parameter can be determined for any subsequent dispense operation using a selected dispense volume target and the pump characteristic function.

After obtaining the characteristic function, photolithography chemical can be dispensed at any of the plurality of target volumes using a pump control parameter for that target volume. The dispense volume can again be measured and verified to be within an allowed error range, such as ±0.02 ml.

In accordance with one embodiment, a photolithography chemical is dispensed onto a surface of a semiconductor substrate in a track lithography tool using a dispense pump operable to receive and dispense a supply of the photolithography chemical. A controller is coupled to the dispense pump and operable to communicate with the dispense pump. The controller is operable to receive dispense volume measurements, either manually or automatically, for a plurality of target volumes of the photolithography chemical and determine an actual dispense volume for each of the plurality of target volumes. The controller is operable to determine a pump characteristic factor for each of the plurality of target volumes based on the determined dispense volume, and fit a pump characteristic function to the characteristic factors for each of the target volumes. The controller is further operable to determine a pump control parameter for a subsequent dispense operation using a selected dispense volume target and the pump characteristic function, and provide a control signal to the dispense pump including the pump control parameter, wherein the dispense pump operates to dispense a volume of the photolithography chemical within ±0.02 ml of the target volume.

In one embodiment the dispense pump is a positive displacement pump including a piston for pushing chemical in a chemical containment chamber and a stepper motor, servo motor, or other appropriate motor or device for driving the piston. The controller then determines the pump control parameter to include a number of drive pulses to be applied to the stepper motor of the dispense pump in order to drive the piston of the dispense pump during a dispense operation.

Other embodiments will be obvious to one of ordinary skill in the art in light of the description and figures contained herein.

### BRIEF DESCRIPTION OF THE DRAWINGS

Various embodiments in accordance with the present invention will be described with reference to the drawings, in which:

FIG. 1 illustrates a chemical dispense system that can be used in accordance with one embodiment of the present invention;

FIG. 2 illustrates a plot of error versus target volume in accordance with one embodiment of the present invention;

FIG. 3 illustrates a plot of incremental volume versus target volume in accordance with one embodiment of the present invention;

FIG. 4 illustrates a plot of pump adjustment factors versus target volume in accordance with one embodiment of the present invention;

FIG. 5 illustrates a plot of error versus target volume in accordance with one embodiment of the present invention;

FIG. 6 illustrates steps of a method in accordance with one embodiment of the present invention;

FIG. 7 illustrates a chemical dispense system that can be used in accordance with one embodiment of the present invention; and

FIG. 8 illustrates an exemplary track lithography tool that can be used in accordance with various embodiments of the present invention.

### DETAILED DESCRIPTION

Systems and methods in accordance with various embodiments of the present invention overcome the afore-mentioned and other deficiencies in existing dispense systems by determining a pump characteristic function that can be used to control the operation of the dispense pump of a chemical dispense system for any given target dispense volume, and for each target disperse volume in a multi-step dispense process. The control in one embodiment takes the form of a number of drive pulses to be applied to the drive motor of the displacement pump. By selecting an appropriate number of drive pulses to be applied, the actual movement and thus the actual displacement of the pump can be controlled during the dispense process in order to account for pressure buildup and other factors during the process. An alternate approach to calibrating dispense volume is described in pending U.S. patent application Ser. No. 11/32,5885, filed Ser. No. 11/32,5885, entitled “Method and Apparatus for Dispense Pump Calibration in a Track Lithography System,” which is hereby incorporated herein by reference.

As described above, track lithography tools dispense precise amounts of expensive lithography chemicals onto substrates to form thin, uniform coatings. For modern lithography processes, the volumes of lithography chemicals such as photoresist that are dispensed per event are small, with volumes typically ranging from about 0.5 ml to about 5.0 ml. The volume of chemical dispensed and the flow rate during a dispense operation, among other variables, are controlled during the process of dispensing the lithography chemicals. Control of the dispense operations in a track lithography tool typically should provide actual dispensed volumes with an accuracy of ±0.02 milliliters (ml) and repeatability from dispense event to dispense event of 3σ<0.02 ml.

A wide variety of photolithography chemicals are utilized in such track lithography tools. For example, photoresist, bottom anti-reflective coating (BARC), top anti-reflective coating (TARC), top coat (TC), Safier, and the like are dispensed onto the substrate. After the selected chemical is dispensed, the substrate sometimes is spun to create a uniform thin coat on an upper surface of the substrate. Generally, to provide the levels of uniformity desired of many photolithography processes, dispense events start with a solid column of chemical. The flow rate is generally set at a predetermined rate as appropriate to a particular chemical deliver process.

As the dispense event is terminated, the fluid is typically drawn back into the dispense line, sometimes referred to as a suck-back process utilizing a suck-back valve. In some track lithography tools, the fluid is brought back into the dispense line about 1-2 mm from the end of the dispense nozzle, forming a reverse meniscus. This suck-back process prevents the lithography chemicals from dripping onto the substrate.

There are many dispense systems available for use with such a track lithography tool, which typically utilize a dispense pump for applying the lithography chemical at the specified flow rate and a filter for filtering any impurities and/or particulates from the lithography chemical before dispense. Typically, the filter is placed downstream of the pump, or between the dispense pump and the nozzle. This is an advantageous configuration since it is necessary to have enough pressure to push the lithography chemical through the filter to meet the necessary flow criteria. This configuration is not optimal, however, as the optimum dispense rate generally is not the same as the optimum filtration rate for a given system or chemical. The optimum rates can vary depend on various factors, such as chemical type, filter type, and pore size. Placing the filter after the dispense pump causes the dispense and filtration rates to be substantially identical, such that typically neither of these flow rates is optimized and instead a compromise is made to obtain an acceptable flow rate for both filtration and dispensation.

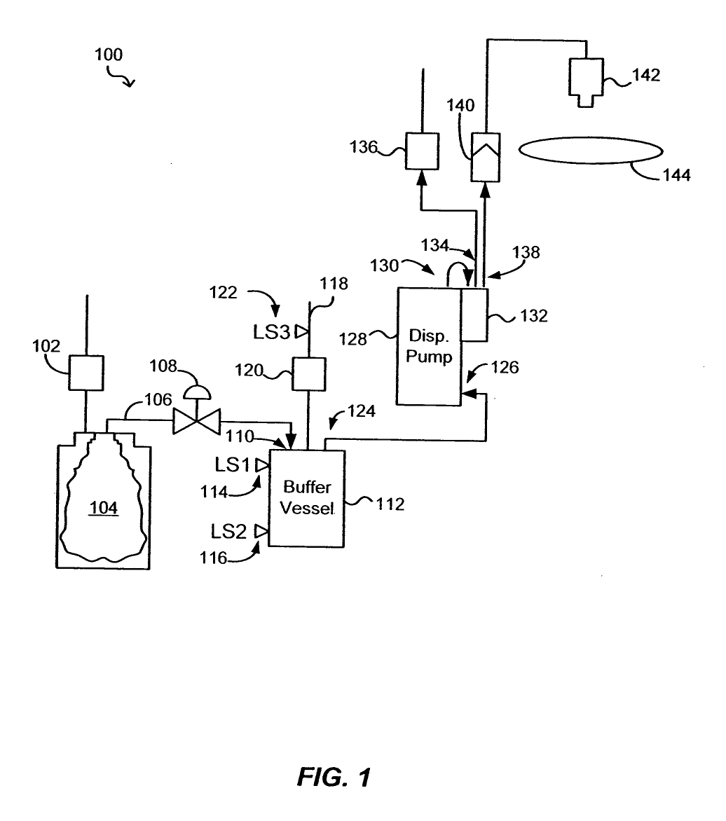

In the system of FIG. 1, a pressure valve 102 used to apply a flow of pressurized gas is coupled to a chemical source bottle 104 containing the photolithography chemical to be dispensed onto the surface of a substrate 144. In one embodiment, the source bottle is a NOWPak® container available from ATMI, Inc., of Danbury, Conn. The container includes a softpack for use with a nitrogen push source, such that the nitrogen does not contact the chemical. The gas source applies pressure to the softpack, pushing chemical out of the chemical source. The output line from the source bottle 104 is coupled to a flow control valve 108 in order to regulate the flow of the photolithography chemical in the fluid line 106. A buffer vessel 112 for receiving and temporarily storing the chemical includes an input port 110, coupled to the fluid line 106, and an output port 124, as well as a venting line 118. The buffer vessel also includes level sensor LS1 (114) and level sensor LS2 (116) for regulating the volume of photolithography chemical present in the buffer vessel 112.

The vent line 118 from the buffer vessel 112 is coupled to a vent valve 120 and a level sensor LS3 (122). The level sensor LS3 (122) serves to monitor the level of fluid passing through the vent valve 120. The output port 124 of the buffer vessel is coupled to input port 126 of the dispense pump 128. A filling or suction cycle of the dispense pump, such as where a piston is retracted at a selected rate, draws chemical into the pump. During a dispense cycle, the piston can push chemical out of the dispense pump at a dispense flow rate. The chemical passes from the outlet 130 of the dispense pump into a chemical filter 132 selected to remove any contaminants or particulates from the chemical flow.

A vent port 134 and an output port 138 can be provided on the chemical filter 132, with a vent valve 136 being coupled to the vent port 134. A shut off/suck-back valve 140 is coupled to the fluid line running from the output port 138 of the chemical filter. From the suck-back valve 140, the photolithography chemical is delivered to the substrate 144 through an appropriately sized dispense nozzle 142. As will be apparent to one of skill in the art, apparatus adapted to chuck and spin the substrate are not illustrated for purposes of clarity. Furthermore, additional dispense systems adapted to provide photolithography chemicals, e.g., multi-nozzle systems, are not illustrated for purposes of clarity and simplicity of understanding.

As discussed above, a dispense system such as that shown in FIG. 1 and can exhibit an unacceptable amount of error in dispense volume and/or dispense rate. Even after standard calibration procedures, these errors may not be acceptable for all applications. As will be evident to one of skill in the art, a dispense volume error in which less chemical than desired is delivered may result in a film of chemical, for example, that does not cover the entire substrate. Alternatively, providing an excess volume of chemical results in waste, which is a manufacturing concern when using chemicals costing as much as $1,000 or more per gallon. Accordingly, embodiments in accordance with the present invention can reduce the dispense volume errors associated with photolithography chemical dispense systems, thereby improving process uniformity and repeatability.

Systems and methods in accordance with embodiments of the present invention avoid the need for iterative recalibration processes in existing systems, wherein recalibration is required after each change in a set point such as a volume, flow rate, or timing point. In one embodiment, a characteristic function is determined for the dispense pump that allows for a determination of the appropriate pump control parameters for any target volume at any starting point. The liquid delivery portion of a dispense system such as that described with respect to FIG. 1 is not truly rigid, as components such as hosing, tubing, and other elements are able to expand and/or compress a given amount under pressure. As such, the pressure applied by the movement of a pump piston at a constant rate will not be constant, even though piston movement is constant, but in fact will increase over time. Therefore, the dispense volume and dispense flow rate are functions not only of the rate of movement of the piston, but also of the pressure build-up within the dispense system. Initial pumping action by the piston builds up pressure in the fluid, but does not result in fluid flow to the extent observed at the end of the pumping action.

Embodiments in accordance with the present invention provide methods of dispensing chemical in a track lithography tool which reduces errors in dispense volume, as well as reducing or eliminating recalibration. In one approach, the pressure applied by a dispense pump is controlled based on the target dispense volume. In a system where a pump drive motor receives a sequence of pulses to actuate the motor and thus drive a piston of the pump to push chemical out of the dispense pump, the number of pulses sent to the drive motor is controlled in order to account for build up of pressure in the system. In other embodiments, control signals or other motor- or pump-driving indicia can be adjusted accordingly using methods and determinations described herein to control the pressure applied by the pump for different target volumes and different starting points. A pump characteristic function can be determined, which can be used to calculate an optimal drive or control signal to be applied to the pump for any given target volume.

FIG. 2 illustrates an exemplary plot of dispense volume error as a function of target volume, as will be discussed below in greater detail. At each target volume level, data is presented for several dispense events with the dispense volume errors being averaged and presented as the solid symbol in the graph and in the legend. These values can represent, for example, a target volume of photolithography chemical dispensed during a photolithography process. For example, target volumes of 1.0, 2.0, 3.0, 4.0, and 5.0 ml are selected for a particular calibration process. As will be evident to one of ordinary skill in the art, the viscosity of the chemical, any solvents pre-wet on the substrate, the substrate spin rate, and the like, can impact this choice of a target volume.

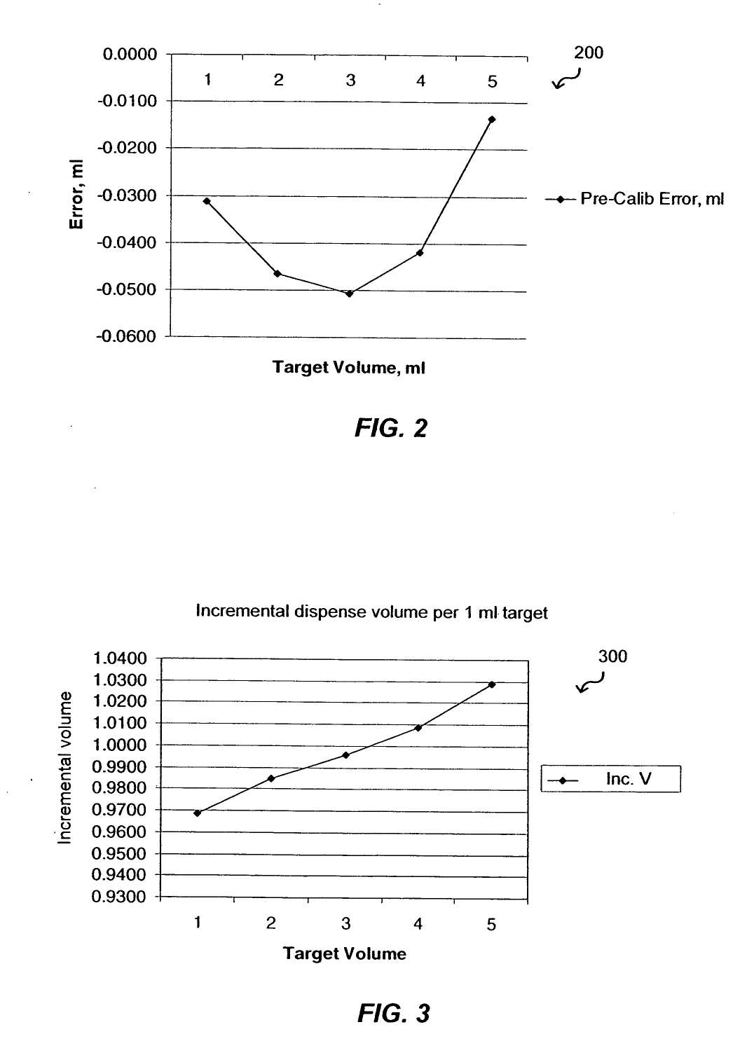

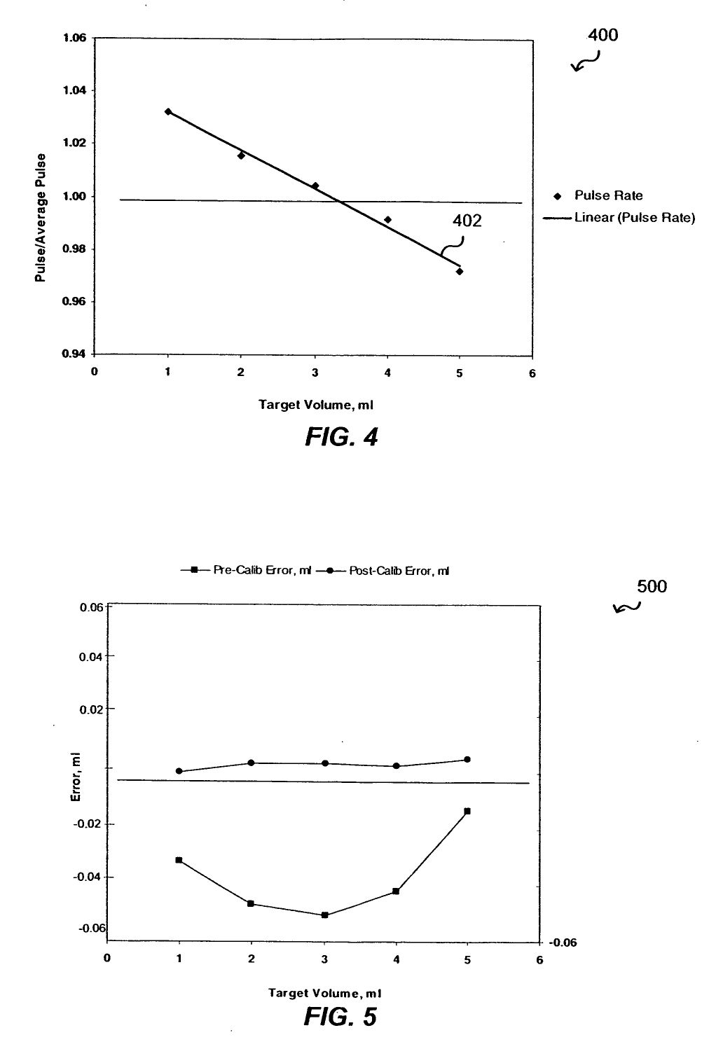

As is described below, a necessary pump control parameter, such as the number of driving pulses applied to a drive motor, decreases with target volume at a substantially linear rate, although other systems may behave differently depending on a variety of factors as would be apparent to one of ordinary skill in the art. Due to this behavior, a linear approximation can be fit to the pump characteristic factors, which then can be used to determine the necessary pulse or drive control parameter for any target volume. For systems without a substantially linear pulse/target volume variation, or for more accurate results, a higher order curve or polynomial could be fit to the data using any appropriate fitting routine known or used in the art. A linear curve fit can provide an estimate of the incremental dispense volume as a function of target volume, as shown in FIG. 3, and/or can provide an estimate of the pump characteristic factor as shown in FIG. 4.

According to some embodiments of the present invention, a pump control parameter calculated as described above is utilized to control a pump drive for a target volume. In other embodiments, the pump control parameter is utilized to generate a control signal that is used to drive the pump. Utilizing embodiments of the present invention, a system operator is provided with additional control over the volume of fluid delivered to the substrate under a variety of dispense parameters. In a particular embodiment, pump software utilizes a desired target volume to calculate a pump control parameter. In some embodiments, the software controls the operation of the photolithography chemical pump, or at least a motor of the pump.

A specific example using such an approach will be described with respect to the data presented in Table 1:

TABLE 1
Experimental results in accordance with one embodiment
Dispense Pump Calibration

| | Target, ml | | | | |
|---|---|---|---|---|---|
| | 1 | 2 | 3 | 4 | 5 |
| Target. Centered | 0.5 | 1.5 | 2.5 | 3.5 | 4.5 |
| Dispense 1, g | 0.7652 | 1.5432 | 2.3298 | 3.1268 | 3.9390 |
| Dispense 2, g | 0.7653 | 1.5429 | 2.3296 | 3.1267 | 3.9389 |
| Dispense 3, g | 0.7651 | 1.5431 | 2.3297 | 3.1261 | 3.9393 |
| Pre-Calib Average, ml | 0.9687 | 1.9534 | 2.9493 | 3.9580 | 4.9867 |
| Pre-Calib Error, ml | −0.0313 | −0.0466 | −0.0507 | −0.0420 | −0.0133 |
| Pulse Factor | 1.0323 | 1.0155 | 1.0042 | 0.9913 | 0.9722 |
| Calculated # Pulses | 2890 | 5739 | 8547 | 11316 | 14043 |
| Dispense 1, g | 0.7900 | 1.5823 | 2.3725 | 3.1618 | 3.9535 |
| Dispense 2, g | 0.7900 | 1.5824 | 2.3723 | 3.1615 | 3.9535 |
| Dispense 3, g | 0.7899 | 1.5823 | 2.3723 | 3.1616 | 3.9536 |
| Post-Calib Average, ml | 1.0001 | 2.0032 | 3.0033 | 4.0025 | 5.0050 |
| Post-Calib Error, ml | 0.0001 | 0.0032 | 0.0033 | 0.0025 | 0.0050 |

This example utilizes a chemical with a 0.790 g/ml density, with a dispense rate of 1.0 ml/s, a pre-dispense of 0.2 ml, a charge rate of 2.0 ml/s, and a vent time of 0.3 seconds. For this particular pump, on average 2,800 pulses are applied to the drive motor in order to displace 1.0 ml of chemical from the pump.

In order to initially calibrate the dispense system, a series of dispense cycles is executed, with at least one or two dispenses at each of a number of target volumes. In this example, three dispense cycles are analyzed for each of five different target volumes. The results for each target volume are then averaged to generate an average actual volume for each target volume. FIG. 2 shows a plot 200 of the error in dispense volume as a function of target volume. It can be seen that the error for each of the 1.0 ml, 2.0 ml, 3.0 ml, and 4.0 ml dispense volumes has more than the acceptable ±0.02 ml margin of error. For example, the 1.0 ml target volume had an average error of −0.0313 ml, while the 2.0 ml target volume had an average error of −0.0466 ml and the 3 ml target volume had an average error of −0.0507 ml. When incremental dispense volumes for a 1 ml target increase for each target volume are plotted as a function of differences between dispense volumes, such as is shown in the plot 300 of FIG. 3, it can be seen that the incremental dispense volumes increase in a substantially linear fashion. For example, the 1.0 ml dispense had an error of −0.0313 ml, while the error for the 2 ml dispense was only −0.0153 ml greater than the error for the 1 ml dispense (for the overall error of −0.0466 ml listed above).

For each of the incremental dispense volumes in the plot of FIG. 3, a determination can be made of how many drive pulses are actually needed to obtain the desired dispense volume at each target volume. For example, the actual average volume of 0.9687 ml for a 1.0 ml dispense was about 3.23% lower than desired. For the 2.0 ml dispense, the actual volume of 1.9534 ml was about 2.38% low, but the difference for that portion beyond the first 1.0 ml of the dispense was only 1.55% low. Accordingly, if the pressure applied by the pump over those dispense periods would have been about 3.23% and 1.55% higher, respectively, the results would have been closer to the desired target volume. Since the pulses in this example drive the motor of the dispense pump, the number of pulses applied to the pump drive motor can be controlled in order to account for the increasing pressure over the dispense process for different target volumes.

For example, FIG. 4 shows a plot 400 approximating a characteristic factor to be applied to the number of pulses per ml to obtain the desired target volume. In this case, the factors are based on an inverse of the normalized difference between target volumes as shown in Table 1. As can be seen, this plot is substantially linear. In this case, a linear fit 402 can be made to the data points to approximate the pump characteristic factor for each target volume. Once an appropriate linear function is determined, the necessary pump control parameters can be obtained by integrating the linear function and multiplying by the number of pulses per milliliter, given by:

$$Adjusted . pulses = ( \frac{1}{2} m ( 2 {t}_{o} + x ) x + bx ) * pp ml$$

or, for the case where t₀=0 (after recharge):

$$Adjusted . pulses = ( \frac{1}{2} {mx}^{2} + bx ) * pp ml$$

where the equation is the standard integral of a linear function (mx+b) over the range from 0 to x, where x is the target volume, m is the slope and b the intercept of the linear function in FIG. 4, to is the starting point, and ppml is the standard number of pulses per milliliter of the pump. For a multiple step process, to is the summation of target volumes for all previous steps. For the special case after a recharge where there are no previous steps volumes, tₒ=0. The result then is an estimation of the number of pulses to be applied to the motor for a given target volume in order to reduce the amount of error in the dispense process. For example, the results in this example show that for a 1.0 ml dispense starting after recharge, 2890 pulses should be applied to the motor instead of the expected 2800 pulses.

FIG. 5 shows the results 500 using these newly adjusted pulse counts. Three dispense cycles were again measured for each target volume, with the average post-calibration error plotted for each. As can be seen, using the calculated pump control parameters the error after calibration is much lower than for pre-calibration. In fact, the errors are less than 0.01 ml, which is well within the 0.02 ml tolerance.

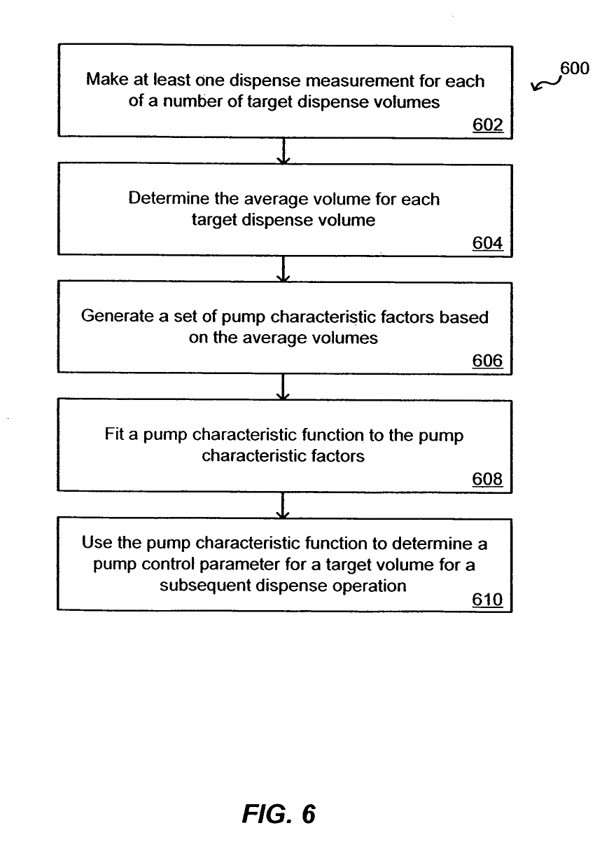

In order to determine the necessary pump adjustments, FIG. 6 illustrates steps of a method 600 that can be used in accordance with one embodiment of the present invention. In this method, at least one dispense measurement is made for each of a plurality of target dispense volumes 602. The average volume for each target dispense volume is determined 604. Using these average volumes, a set of pump characteristic factors is generated 606 based on the incremental dispense volume values for each target value. A pump characteristic function then is fit to the pump characteristic factors 608. In the example above a linear fit was sufficient, although other fit functions can be used as appropriate. Once a pump characteristic function is determined, the appropriate pump control parameter can be determined for any target volume and for each step in a multiple step process 610. In the example above, this takes the form of integrating over the fit function for the target volume to determine a number of pulses to be applied to the pump motor for the target volume. In other embodiments, this can take the form of any other control parameter or value applied to the pump in order to control the dispense volume.

The individual steps illustrated of this method may include multiple sub-steps that may be performed in various sequences as appropriate to the individual step. Furthermore, other alternatives can also be provided where steps are added, one or more steps are removed, or one or more steps are provided in a different sequence without departing from the scope of the claims herein. One of ordinary skill in the art would recognize many variations, modifications, and alternatives.

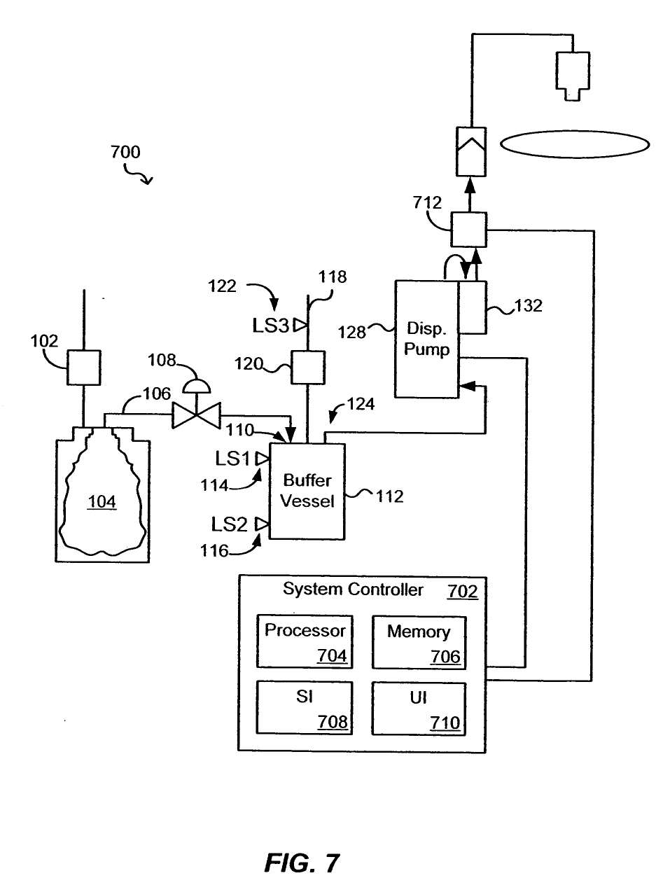

As discussed above, the measurements and/or adjustments can be made manually by an operator or technician, or automatically using an open- or closed-loop system. For example, FIG. 7 shows an exemplary system 700 in accordance with one embodiment using a closed feedback approach. Reference numbers are carried over from FIG. 2 where appropriate for simplicity, but this should not be read as a limitation of the various embodiments. In this system a system controller 702 is in electrical communication with a flow monitor 712, or other device for measuring the accuracy of the dispense process, as well as with the dispense pump. Although the flow monitor is shown along the dispense line for simplicity, it should be understood that it can be advantageous in other systems to place the flow monitor near the nozzle as known in the art. For each dispense operation during a calibration cycle, the flow monitor, for example, can measure the actual dispense amount for any target volume. The use of a flow monitor in this embodiment allows for the calibration to be done automatically using the system controller. The flow monitor can be any appropriate device for metering flow, such as an electronic balance that can communicate results to the controller, a flow sensor (mounted in the line) that can send volume information electronically to the system controller, or an optical sensor (mounted near the nozzle tip) that can send flow images to the system controller for calculating a volume. The system controller 702 can receive a measurement signal from the flow monitor 712 containing the volume or flow information, and can determine necessary pump control parameters as discussed above using a processor 704, memory 706, system interface 708, and any other component known or used in the art for receiving a measurement signal, retrieving a result, computing an adjustment, and outputting a signal in response thereto. After the system controller determines the necessary pump control parameter for the next dispense cycle, the system controller 702 can output a control signal to the dispense pump, which can include the appropriate number of pulses for the next target volume. In other embodiments where the system controller actually supplies the pulses, the system controller can output the number of pulses directly to the pump and/or drive motor. The system controller 702 also can include a user interface 710 allowing an operator to interface with the system controller, such as to specify the next target volume or manually adjust pulse counts. Where measurements are made external to the system, a user or operator can input the measurement results for computation.

Track Lithography Tool

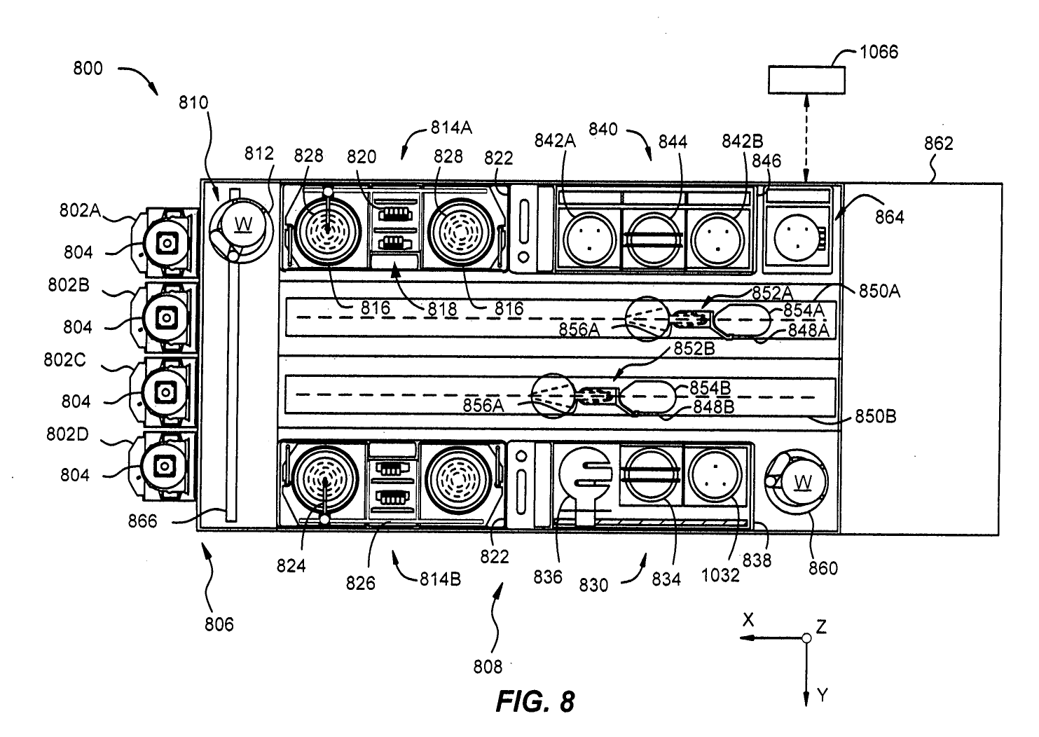

FIG. 8 is a plan view of an exemplary track lithography tool 800 which can be used with various embodiments in accordance with the present invention. As illustrated in FIG. 8, the track lithography tool 800 contains a front end module 806 (sometimes referred to as a factory interface or FI) and a process module 808. In other embodiments, the track lithography tool 800 includes a rear module (not shown), which is sometimes referred to as a scanner interface. Front end module 806 generally contains one or more pod assemblies or FOUPS (e.g., items 802A-D) and a front end robot assembly 810 including a horizontal motion assembly 866 and a front end robot 812. The front end module 806 may also include front end processing racks (not shown). The one or more pod assemblies 802A-D are generally adapted to accept one or more cassettes 804 that may contain one or more substrates or wafers that are to be processed in the track lithography tool 800. The front end module 806 may also contain one or more pass-through positions (not shown) to link the front end module 806 and the process module 808.

The process module 808 generally includes a number of processing racks 814A, 814B, 830, and 840. As illustrated in FIG. 8, some processing racks 814A and 814B in this embodiment each include a coater/developer module with a shared dispense 122. A coater/developer module with this shared dispense 822 includes two coat bowls 816 positioned on opposing sides of a shared dispense bank 818, which contains a number of nozzles 820 providing processing fluids (e.g., bottom anti-reflection coating (BARC) liquid, resist, developer, and the like) to a wafer mounted on a substrate support 1028 located in the coat bowl 816. In the embodiment illustrated in FIG. 8, a dispense arm 824 sliding along a track 826 is able to pick up a nozzle 820 from the shared dispense bank 818 and position the selected nozzle over the wafer for dispense operations. Of course, coat bowls with dedicated dispense banks are provided in alternative embodiments.

Processing rack 830 includes an integrated thermal unit 838 including a bake plate 832, a chill plate 834, and a shuttle 836. The bake plate 832 and the chill plate 834 are utilized in heat treatment operations including post exposure bake (PEB), post-resist bake, and the like. In some embodiments, the shuttle 836, which moves wafers in the x-direction between the bake plate 832 and the chill plate 834, is chilled to provide for initial cooling of a wafer after removal from the bake plate 832 and prior to placement on the chill plate 834. Moreover, in other embodiments, the shuttle 836 is adapted to move in the z-direction, enabling the use of bake and chill plates at different z-heights. Processing rack 840 includes an integrated bake and chill unit 846, with two bake plates 842A and 842B served by a single chill plate 844.

One or more robot assemblies (robots) 848A, 848B are adapted to access the front-end module 806, the various processing modules or chambers retained in the processing racks 814A, 814B, 830, and 840, and the scanner 862. By transferring substrates between these various components, a desired processing sequence can be performed on the substrates. The two robots 848A, 848B illustrated in FIG. 8 are configured in a parallel processing configuration and travel in the x-direction along horizontal motion assembly 850A, 850B. Utilizing a mast structure (not shown), the robots 848A, 848B are also adapted to move in a vertical (z-direction) and horizontal directions, i.e., transfer direction (x-direction) and a direction orthogonal to the transfer direction (y-direction). Utilizing one or more of these three directional motion capabilities, the robots 848A, 848B are able to place wafers in and transfer wafers between the various processing chambers retained in the processing racks that are aligned along the transfer direction.

The first robot assembly 848A and the second robot assembly 848B here are adapted to transfer substrates to the various processing chambers contained in the processing racks 814A, 814B, 830, and 840. In one embodiment, to perform the process of transferring substrates in the track lithography tool 800, robot assembly 848A and robot assembly 848B are similarly configured and include at least one horizontal motion assembly 850A, 805B, at least one vertical motion assembly 854A, 854B, and robot hardware assemblies 852A, 852B supporting robot blades 856A, 856B. Robot assemblies 848A, 848B are in communication with a system controller 866. In the embodiment illustrated in FIG. 80, a rear robot assembly 860 is also provided.

The scanner 862, which in one embodiment may be purchased from Canon USA, Inc. of San Jose, Calif., Nikon Precision Inc. of Belmont, Calif., or ASML US, Inc. of Tempe Ariz., is a lithographic projection apparatus used, for example, in the manufacture of integrated circuits (ICs). The scanner 862 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 814A, 814B, 830, and 840 can contain multiple processing modules in a vertically stacked arrangement. That is, each of the processing racks may contain multiple stacked coater/developer modules with shared dispense 822, multiple stacked integrated thermal units 838, multiple stacked integrated bake and chill units 846, or other modules that are adapted to perform the various processing steps required of a track photolithography tool. As examples, coater/developer modules with shared dispense 1022 may be used to deposit a bottom antireflective coating (BARC) and/or deposit and/or develop photoresist layers. Integrated thermal units 838 and integrated bake and chill units 846 may perform bake and chill operations associated with hardening BARC and/or photoresist layers after application or exposure.

In one embodiment, a system controller 866 is used to control all of the components and processes performed in the cluster tool 800. The controller 866 is generally adapted to communicate with the scanner 862, monitor and control aspects of the processes performed in the cluster tool 800, and is adapted to control all aspects of the complete substrate processing sequence. The controller 866, which is typically a microprocessor-based controller, is configured to receive inputs from a user and/or various sensors in one of the processing chambers and appropriately control the processing chamber components in accordance with the various inputs and software instructions retained in the controller's memory. The controller 866 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 866 determines which tasks are performable in the processing chamber(s). Preferably, the program is software readable by the controller 866 and includes instructions to monitor and control the process based on defined rules and input data.

Storage media and computer-readable media for containing code, or portions of code, can include any appropriate media known or used in the art, including storage media and communication media, such as but not limited to volatile and non-volatile, removable and non-removable media implemented in any method or technology for storage and/or transmission of information such as computer readable instructions, data structures, program modules, or other data, including RAM, ROM, EEPROM, flash memory or other memory technology, CD-ROM, digital versatile disk (DVD) or other optical storage, magnetic cassettes, magnetic tape, magnetic disk storage or other magnetic storage devices, data signals, data transmissions, or any other medium which can be used to store or transmit the desired information and which can be accessed by the computer. Based on the disclosure and teachings provided herein, a person of ordinary skill in the art will appreciate other ways and/or methods to implement the various embodiments.

It is to be understood that embodiments of the invention are not limited to use with a track lithography tool such as that depicted in FIG. 8. Instead, embodiments of the invention may be used in any track lithography tool including the many different tool configurations described in U.S. patent application Ser. No. 11/315,984, entitled “Cartesian Robot Cluster Tool Architecture” filed on Dec. 22, 2005, which is hereby incorporated by reference for all purposes and including configurations not described in the above referenced application.

A particle detection apparatus 864 also can be provided as a module in the track lithography tool 800. This particle detection apparatus 864 is serviced by one or both of the robot assemblies 848A, 848B and is utilized, as described more fully throughout the present specification, to detect particles present on the backside of a wafer or substrate. The use of the particle detection apparatus may occur before or after several of the wafer processes performed within the track lithography tool 800. These wafer processing include coat, develop, bake, chill, exposure, and the like. In a particular embodiment, the substrate is scanned for particles prior to processing by the scanner. In alternative embodiments, the particle detection apparatus 864 is located external to the track lithography tool 800 in a separate stand-alone test module. One of ordinary skill in the art would recognize many variations, modifications, and alternatives.

The examples and embodiments described herein are for illustrative purposes only. Various modifications or changes in light thereof will be suggested to persons skilled in the art and are to be included within the spirit and purview of this application and scope of the appended claims. It is not intended that the invention be limited, except as indicated by the appended claims.

What is claimed is:

1. A method of dispensing a photolithography chemical onto a substrate positioned in a track lithography tool, the method comprising:
dispensing photolithography chemical at each of a plurality of target volumes;
calculating an actual dispense volume for each of the plurality of target volumes;
determining a pump characteristic factor for each of the plurality of target volumes based on the respective actual dispense volume;
fitting a pump characteristic function to the pump characteristic factors for each of the plurality of target volumes; and
determining a pump control parameter for a subsequent dispense operation using a selected dispense volume target and the pump characteristic function.

2. A method according to claim 1, further comprising:
dispensing photolithography chemical at any of the plurality of target volumes using the determined pump control parameter.

3. A method according to claim 2, further comprising:
verifying that the dispense volume using the determined pump control parameter is within an allowed error range.

4. A method according to claim 1, wherein:
fitting a pump characteristic function to the pump characteristic factors includes fitting a linear function to the pump characteristic factors.

5. A method according to claim 1, wherein:
determining a control parameter includes determining a number of drive pulses to be applied to a motor of a dispense pump in order to drive a piston of the dispense pump.

6. A method according to claim 1, further comprising:
applying the pump control parameter to the dispense pump for the subsequent dispense operation.

7. A method according to claim 1, wherein:
the photolithography chemical is at least one of a BARC, TARC, TC, ARC, SOD, SOP, SOG, or a Shrink.

8. A method according to claim 1, further comprising:
delivering a volume of the photolithography chemical within ±0.02 ml of the target volume.

9. A method according to claim 1, wherein:
the pump characteristic function is operable to be used for subsequent target volumes without recalibration.

10. A method according to claim 1, wherein:
the pump characteristic function is operable to be used to determine pump control parameters for each step in a multiple dispense step process.

11. An apparatus for dispensing a photolithography chemical onto a surface of a semiconductor substrate in a track lithography tool, the apparatus comprising:
a dispense pump operable to receive and dispense a supply of the photolithography chemical;
a controller coupled to the dispense pump, the controller operable to:
receive dispense volume measurements for a plurality of target volumes of the photolithography chemical;
determine a pump characteristic factor for each of the plurality of target volumes based on the dispense volume measurements;
fit a pump characteristic function to the pump characteristic factors for each of the plurality of target volumes;
determine a pump control parameter for a subsequent dispense operation using a selected dispense volume target and the pump characteristic function; and
provide a control signal to the dispense pump using the pump control parameter, wherein the dispense pump operates to dispense a volume of the photolithography chemical within ±0.02 ml of the target volume.

12. An apparatus according to claim 11, wherein:
the controller is further operable to verify that the dispense volume using the pump control parameter is within an allowed error range

13. An apparatus according to claim 11, wherein:
the controller is operable to fit a linear function to the pump characteristic factors.

14. An apparatus according to claim 11, wherein:
the dispense pump is a positive displacement pump including a piston for pushing chemical in a chemical containment chamber and a drive motor for driving the piston.

15. An apparatus according to claim 14, wherein:
the controller is further operable to determine a pump control parameter including a number of drive pulses to be applied to the drive motor of the dispense pump in order to drive the piston of the dispense pump during a dispense operation.

16. An apparatus according to claim 11, wherein:
the photolithography chemical is at least one of a BARC, TARC, TC, ARC, SOD, SOP, SOG, or a Shrink.

17. An apparatus according to claim 11, wherein:
the controller is further operable to determine pump control parameters for each step in a multiple dispense step process.

18. A computer program product stored on a computer-readable storage medium for operating a track lithography tool adapted to dispense a photolithography chemical onto a semiconductor substrate, the computer program product comprising:
computer program code for receiving dispense volume measurements for a plurality of target volumes of the photolithography chemical;
computer program code for determining a pump characteristic factor for each of the plurality of target volumes based on the dispense volume measurements;
computer program code for fitting a pump characteristic function to the pump characteristic factors for each of the plurality of target volumes; and
computer program code for determining a pump control parameter for a subsequent dispense operation using a selected dispense volume target and the pump characteristic function.

19. A computer program product according to claim 18, further comprising:
computer program code for providing a control signal to the dispense pump including the pump control parameter, wherein the dispense pump operates to dispense a volume of the photolithography chemical within ±0.02 ml of the target volume.

20. A computer program product according to claim 18, wherein:
the chemical pump is adapted to deliver the photolithography chemical to the substrate within ÷0.02 ml of the target volume.
